(19) United States
(12) Patent Application Publication
(10) Pub. No.: US 2025/0093427 A1
(43) Pub. Date: Mar. 20, 2025

(54) MODULAR BATTERY CELL TEST AND BATTERY PACK VERIFICATION SYSTEM AND METHOD

(71) Applicant: YOU ONE POLYMER CO., LTD., Incheon (KR)

(72) Inventor: HAEMYOUNG LEE, Gyeonggi-do (KR)

(21) Appl. No.: 18/470,441

(22) Filed: Sep. 20, 2023

(51) Int. Cl. G01R 31/396; G01R 31/367

(52) U.S. Cl. CPC G01R 31/396; G01R 31/367

(57) ABSTRACT

A modular battery cell test and battery pack verification system and method are disclosed. A modular battery cell test and battery pack verification system according to one embodiment of the present invention, for testing a battery cell and verifying a battery pack, comprises a cell battery test apparatus comprising a plurality of cell test modules for performing tests on single battery cells, and for performing verification on a virtual battery pack in connection with said cell test modules; a main control unit for transmitting control signals for test and verification to said cell test modules; and a main battery for supplying power to said cell battery test apparatus or recovering power discharged from said cell battery test apparatus.

### TECHNICAL FIELD

The present invention relates to modular battery cell testing and battery pack verification systems and methods.

### RELATED ARTS

Secondary batteries, represented by lithium batteries, such as lithium ion (Li-ion) or lithium polymer (Li-polymer), or lithium iron phosphate batteries (LiFeP04), are becoming an indispensable core energy source for Industry 4.0. Thanks to their dramatic performance improvements and increased capacity, they are actively used in the mobility industry, such as electric vehicles (EVs) and e-bikes, and are rapidly expanding to replace internal combustion engines across industries, including heavy machinery.

However, despite the rapid increase in performance, the unbalanced nature of battery cells hasn't been fully addressed, so there are some inherent problems. These include reliability issues such as battery explosions that make the news once or twice a year, battery packs that don't hold their capacity even when brand new, and uneven lifespan issues such as batteries failing within the warranty period.

In Korean Public Patent No. 10-2008-0042227, method for verifying rechargeable battery capacity is disclosed.

### SUMMARY

### Technical Objectives

The present invention is to provide a modular battery cell test and battery pack verification system and method that can overhaul a large number of produced battery cells and then group and categorize battery cells with the same or very similar characteristics.

The present invention is to provide a modular battery cell test and battery pack verification system and method for multiple battery cells that can be tested after testing on a single battery cell has been completed, and in that state, by configuring series and/or parallel connection information to immediately create a situation identical to that of an actual battery pack.

The present invention is to provide a modular battery cell test and battery pack verification system and method that can save energy by recovering power consumed during the testing process, storing it in the main battery and reusing it.

Other objects of the present invention will be readily understood though the following description.

### Technical Solutions

According to one aspect of the present invention, there is provided a modular battery cell test and battery pack verification system for testing a battery cell and verifying a battery pack, comprises a cell battery test apparatus comprising a plurality of cell test modules for performing tests on single battery cells, and for performing verification on a virtual battery pack in connection with said cell test modules; a main control unit for transmitting control signals for test and verification to said cell test modules; and a main battery for supplying power to said cell battery test apparatus or recovering power discharged from said cell battery test apparatus.

Said cell test module may comprise an isolation power supply and single cell test circuit for providing independent power and performing predetermined cell tests on said single cell; and an input and output terminals that receive control signals from said main control unit, transmit test results, and are hardware switched according to series and parallel connection information after test completion.

Said cell battery test apparatus may cause a plurality of said cell test modules to be connected in an XY matrix manner, and wherein module connections are controlled to avoid single cells that are determined to be bad cells as a result of the test, thereby a packing combination for a virtual battery pack may be created.

Said main battery may be connected to a bidirectional grid inverter to enable power sharing with other systems.

A data server storing test results, and configuring a packing combination for a virtual battery pack; and a printer for printing at least one of cell information corresponding to said test results, and pack information corresponding to verification results for said virtual battery pack, in a form attachable to said single battery cell, may be included.

Or a data server for storing test results and configuring packing combinations for a hypothetical battery pack; and a laser marking apparatus that, upon completion of the test, rotates said single cell to directly imprint at least one of cell information corresponding to said test results, and pack information corresponding to verification results for said virtual battery pack, on a surface of said single cell, may be included.

Meanwhile, according to another aspect of the present invention, there is a cell test module for performing tests on battery cells, comprising: an isolation power supply and single battery cell test circuit for providing independent power and performing predetermined cell tests on said battery cells; a communication terminal for receiving control signals from a main control unit and transmitting test results; a module connection terminal connecting between a front module and a back module; a power terminal connecting VCC and GND for verification of a virtual battery pack; and a plurality of switches controlling connections between said single cell, said isolation power supply and single cell test circuit, said module connection terminals, and said power terminals.

Said plurality of switches may comprise a first switch (S1) interposed between a positive electrode of said battery cell and said isolation power supply and single cell test circuit; a second switch (S2) interposed between a negative electrode of said battery cell and said isolation power supply and single cell test circuit; with a third switch (S3), a fourth switch (S4), a fifth switch (S5), and a sixth switch (S6) sequentially disposed between a first module connection terminal connecting to the front module and a second module connection terminal connecting to the back module; and a seventh switch (S7), an eighth switch (S8), a ninth switch (S9), and a tenth switch (S10) disposed sequentially between a VCC terminal and a GND terminal among said power terminals.

Only said first switch and said second switch may be in the ON state when testing said battery cell.

When said battery cell is a normal cell, said first switch and said second switch may be OFF during verification on a virtual battery pack, and the switch connections may be controlled to pass through said battery cell by controlling the ON/OFF of said third switch to said tenth switch.

If said battery cell is a bad cell, said first switch and said second switch may be turned OFF during verification of a virtual battery pack, and said switch connection may be controlled to bypass said battery cell by controlling the ON/OFF of said third switch to said tenth switch.

Other aspects, features and advantages other than those described above will become apparent from the following drawings, claims and detailed description of the invention.

### Effects of Invention

According to an embodiment of the present invention, after overhauling a large number of produced battery cells, battery cells having the same or extremely similar characteristics can be grouped and categorized together.

Furthermore, it has the effect that after the test of a single battery cell is completed for a plurality of battery cells, it is possible to configure series and/or parallel connection information in that state and immediately configure and test the same situation as an actual battery pack.

In addition, the power consumed during the test process can be recovered, stored in the main battery, and reused, thereby saving energy.

### BRIEF DESCRIPTION OF ACCOMPANYING DRAWINGS

FIG. 1 is a drawing illustrating the configuration of a modular battery cell test and battery pack verification system, according to one embodiment of the present invention,

FIG. 2 is a drawing illustrating a configuration of a cell test module included in a cell battery test device,

FIG. 3 is a drawing depicting a circuit configuration of a cell test module according to one embodiment of the present invention, depicting a reset state after power is applied,

FIG. 4 is a diagram of a switch connection when testing a single cell,

FIG. 5 is a switch connection diagram in series connection,

FIG. 6 is a switch connection diagram for bad cell avoidance,

FIG. 7 is a conceptual view of the input and output connections and power supply for each test module,

FIG. 8 is a conceptual diagram showing the connection relationship with bad cell avoidance.

### DETAILED DESCRIPTION

The invention can be modified in various forms and specific embodiments will be described below and illustrated with accompanying drawings. However, the embodiments are not intended to limit the invention, but it should be understood that the invention includes all modifications, equivalents, and replacements belonging to the concept and the technical scope of the invention.

If it is mentioned that an element is “connected to” or “coupled to” another element, it should be understood that still another element may be interposed therebetween, as well as that the element may be connected or coupled directly to another element. On the contrary, if it is mentioned that an element is “connected directly to” or “coupled directly to” another element, it should be understood that still another element is not interposed therebetween.

Terms such as first, second, etc., may be used to refer to various elements, but, these element should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

Elements of an embodiment described below with reference to the accompanying drawings are not limited to the corresponding embodiment, may be included in another embodiment without departing from the technical spirit of the invention. Although particular description is not made, plural embodiments may be embodied as one embodiment.

In describing the invention with reference to the accompanying drawings, like elements are referenced by like reference numerals or signs regardless of the drawing numbers and description thereof is not repeated. If it is determined that detailed description of known techniques involved in the invention makes the gist of the invention obscure, the detailed description thereof will not be made.

Terms such as ˜part, ˜unit, ˜module mean an element configured for performing a function or an operation. This can be implemented in hardware, software or combination thereof.

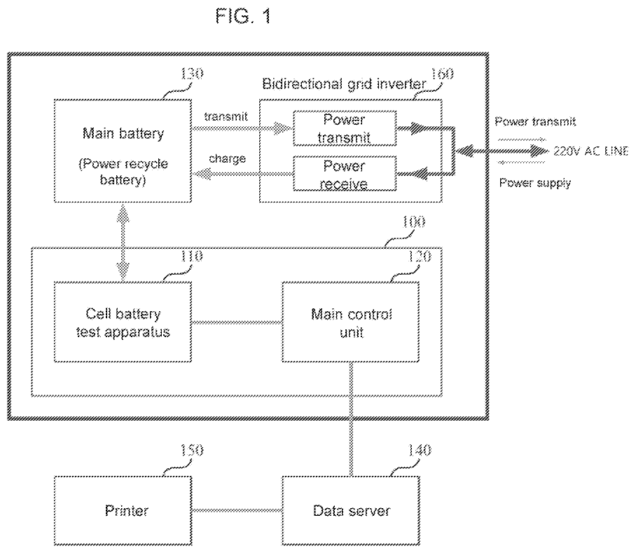

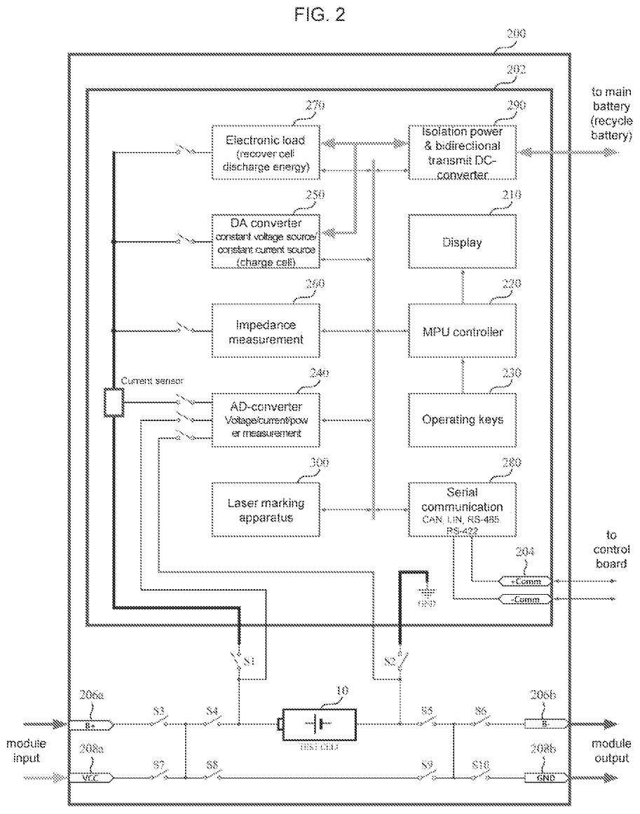

FIG. 1 is a diagram illustrating the configuration of a modular battery cell test and battery pack verification system according to one embodiment of the present invention, and FIG. 2 is a diagram illustrating the configuration of a cell test module included in the cell battery test device.

Secondary batteries have a structure in which electromotive force is generated by chemical reaction. Each battery cell has a challenging requirement to maintain a uniform concentration of internal electrolyte to maintain the correct electromotive force and capacity. Though factors like electrodes also hinder the accurate maintenance of the electromotive force and capacity, the uniformity of the electrolyte's concentration is the primary concern.

High-reliability battery manufacturers control the concentration of the electrolyte to keep it within tolerances, but despite their efforts, it is not practical to manufacture batteries with 100% identical characteristics. Manufactured batteries are shipped with slight variations in battery characteristics such as voltage, capacity, and internal resistance.

It is common for secondary cells to be connected in series to produce the required voltage, paralleled in groups to increase the current, and packaged to form a battery pack. As a precaution, it is required to pack batteries with the same characteristics together, otherwise, cell balancing problems may occur, in which the voltage between battery cells gradually varies as charging and discharging continues, causing the capacity to decrease rapidly, or the entire battery pack to fail with only one or two cells degrading in performance, and in severe cases, the battery being charged may explode.

A good way to maintain cell balance is to group battery cells with the same or very similar characteristics. Since battery cell production is not subject to the same precise processes as semiconductors, most battery cells are subject to small and large tolerances.

Even if you use a highly reliable manufacturer's product, it will only take a little longer for it to become unbalanced.

A secondary way to solve the problem of maintaining cell balance is to use additional cell balance circuitry such as a battery management system (BMS). Passive BMSs are inexpensive, but their balancing currents are small, so they work well in the early stages when balancing distortions are small, but over time they become ineffective when the voltage between cells varies significantly. There are also high-performance active BMSs with much larger balancing currents, but they are quite expensive.

Therefore, noting that a fundamental solution to the imbalance of the battery cells comprising a battery pack is to use battery cells with 100% identical characteristics, the modular battery cell and battery pack verification system according to one embodiment of the present invention is characterized in that the produced battery cells are overhauled in bulk and then sorted so that battery cells with identical or extremely similar characteristics can be grouped together. The goal is to identify battery cells with identical or very similar characteristics and pack them together to maximize the time until they become unbalanced, thus extending the life of the battery.

In order to realize this, various additional instruments such as electronic loads, current sources, voltage sources, impedance meters, etc. are required, but the disadvantage is that existing instruments are basically designed to test a single battery cell, which requires a huge number of instruments for mass testing, which increases the purchase cost.

In addition, depending on the time required to inspect a single battery cell, up to 9 hours are required, so it takes a lot of time to inspect thousands to tens of thousands of battery cells in bulk, and the labor cost of the equipment manager is also a major barrier.

Therefore, the present embodiment aims to provide a cell balance test and verification device that is implemented in the form of a compact module with multiple functions by simplifying only the necessary functions, and a plurality of modules are connected to a server by serial communication and operated.

The modular battery cell test and battery pack verification system according to this embodiment also has an energy recovery function that can recover tens of KW of power consumed in large quantities during the discharge test process and store it in the main battery for reuse.

Referring to FIG. 1, the modular battery cell testing and battery pack verification system 100 according to this embodiment includes a cell battery test device 110 and a main battery 130. It may further include a data server 140 and/or a printer 150, as desired.

The cell battery test device 110 has a plurality of cell test modules 200 for measuring the capacity and characteristics of a single battery cell (single cell). The cell test modules 200 have power and serial communication connections between them, allowing them to be connected in series and in parallel for battery cells that have been determined to be good (healthy), to validate their performance when packed into a single battery pack.

The main control unit 120 is connected to the cell battery test device 110, and generates and delivers control signals that enable testing of single battery cells, verification of battery packs, etc. to be performed. The main control unit 120 may include components such as a main control MPU, data memory, a control panel, a monitor, a keyboard, and a LAN port.

The data server 140 stores test results performed on the cell battery test device 110. Battery cells that are determined to have the same or very similar characteristics can be grouped together for verification of their performance as a battery pack.

By sequentially listing a plurality of battery cells according to their test results, battery cells with similar characteristics can be placed adjacent to each other and grouped together for battery pack verification.

Additionally, the latter printer 150 can be controlled to print cell information corresponding to the test results for each battery cell tested. The printed cell information may be implemented as an attachable identification code (e.g., barcode, QR code, etc.) that may be affixed to a surface of the battery cell to facilitate identification.

Alternatively, the printer 150 can be controlled to print, for each battery cell, pack information corresponding to the battery pack allocated based on the performance verification results. The printed pack information can be implemented as an affixable identification code (e.g., barcode, QR code, etc.) that can be affixed to the surface of a battery cell to facilitate identification during subsequent battery pack configuration.

The cell information and pack information may be printed separately or together as required.

The identification code affixed to the battery cell, when read by a reader or smartphone or the like, can immediately provide information about the battery cell (cell information and/or pack information) from the data server 140, such as test history, measurement results, characteristics, etc.

Alternatively, each of the cell test modules 200 of the cell battery test apparatus 110 may be provided with a laser marking apparatus 300 to allow for direct imprinting of the tested battery cell on its surface.

In this embodiment, the battery cell 10 under test may be cylindrical. Accordingly, the independent laser marking apparatus 300 included with each cell test module 200 may leave the battery cell 10 in place after cell testing and, for battery cells 10 that are determined to be good, rotate them at a predetermined speed using rotary means to imprint cell information and/or pack information directly on the surface of the cell.

The main battery 130 may provide the power required for the cell battery test device 110 to operate, i.e., it may provide power for the system as a whole.

The main battery 130 may be connected to the cell battery test device 110 to provide charging power during charge testing.

It can also act as a static load (dummy load) during discharge testing and recover power as it is discharged. In this case, the main battery 130 may function as a power recycling battery corresponding to an energy recovery device. For example, it may be implemented as a minimum 24V 200 A (4.8 KW) rechargeable battery stack, and there is no limit to increasing the battery stack capacity. Components such as an active BMS, current/voltage monitor, and power maintenance circuitry may be provided to enable reliable energy recovery.

The main battery 130 can export or accept power through the bidirectional grid inverter 160 to enable power sharing. The bidirectional grid inverter 160 may include components for power sharing, such as current sensing circuitry, voltage maintenance circuitry, instantaneous overcurrent protectors, and the like.

In addition, the main battery 130 may perform a UPS function in the event of a power outage.

The bidirectional grid inverter 160 may include a power receiving unit and a power transmitting unit. The power receiving unit relates to power for charging the main battery 130, which is taken from the AC line to replenish the main battery 130 during power shortages. The power transmission unit is the part that exports the surplus power of the main battery 130 via the AC line.

Referring now to FIG. 2, a configuration of a cell test module 200 included in a cell battery test device 110 is disclosed.

The cell test module 200 is a module with a set of functions for testing one battery cell (single cell).

The cell test module 200 may be operable in serial communication with the main control unit 120. It can also be switched to a manual mode for independent operation by the user.

The cell test module 200 is provided with a socket on the front for inserting a test cell. It has a display 210 on the front for displaying relevant information. Below or to the side of the front, there may be knobs or operating keys 230 for adjusting parameters.

At the rear, there are socket-type connections for power supply and communication line connection, and a plug-in method is applied to connect by inserting a plug, which has the advantage of convenient expansion and management without additional tools. In addition, the size and shape of the sockets are implemented differently to prevent misconnection.

The purpose of each socket is separated into power supply, discharge power return, cell series-parallel selector, serial communication, etc. They can be interconnected with other modules by accepting them as input sockets and passing them as output sockets.

The connection method of the test modules can be variously configured in series, parallel, mixed series and parallel, etc.

A plurality (e.g., up to 512) of cell test modules 200 may be connected to the main control unit 120 via serial communication, e.g., CAN, LIN, RS-485, RS-422, etc. The power required by the cell test modules 200 may be supplied by the main battery 130. Replenishment of power losses in the main battery 130 is performed by the bidirectional grid inverter 160.

The main control unit 120 may be provided with a LAN port for interfacing with the data server 140, and a serial communication port including wireless communication.

In addition, a printer 150 for assigning serial numbers and QR labels for long-term information management to battery cells that pass the test, and a scanner for reading battery information may be connected.

The data logger function accumulates the data extracted during the verification of the test cell or battery pack and transmits the data upon request from the data server 140.

The data server 140 can instantly configure and simulate packing combinations to make battery packs for the battery cells that have been tested and found to be good. Series and/or parallel connection switches can be combined in a matrix manner.

By leaving the tested single cell in the cell test module 200, configuring the serial and parallel connection information in the main control unit 120 and sending the code to each cell test module 200, the input and output terminals in the cell test module 200 are hardware switched between the single cells to form a series and/or parallel configuration. Therefore, the same situation as the actual battery pack can be immediately configured and verified, and the serial and/or parallel connections can be reconfigured and verified for various combinations.

Traditionally, for battery pack manufacturing and verification, once specifications such as voltage, current, and total capacity are determined, single cell cells are assembled in series or parallel and connected by spot welding for testing. At this time, if there is a change in specifications, the already welded batteries cannot be reused and must be discarded, and if only one cell fails during the test, the battery pack itself must be discarded, resulting in significant cost losses.

In the simulation method according to the present embodiment, welding is not required, and even if the series or parallel configuration of the battery cells is incorrect or the specifications are changed, they can be reconfigured using software, and even if a defect occurs during the test, the battery cells can be replaced immediately, preventing costly losses.

The cell test module 200 may include single cell test circuits such as a voltage/current measurement circuit 240, a constant voltage source/constant current source 250, and an impedance measurement circuit 260 for characterization tests on battery cells. These circuits may be powered and operated by the isolator power section 290, which is a bidirectional power transfer device.

In conventional discharge testing of battery cells and battery packs, energy is dissipated as heat in the load resistance. However, in this embodiment, the load resistor is not used, and the entirety of the discharge energy is recovered using an energy recovery device and charged to the main battery 130.

The charged recycled energy is later reused to charge the battery cells and battery pack, and the excess energy is transferred to other systems via the bidirectional grid inverter 160 for reuse, which can significantly reduce the consumption of 220V commercial power and reduce carbon emissions.

Some of the energy lost in this process is supplemented by taking it from the 220V commercial power supply, and the supplemental power required in this system of about 500 test modules is about a few hundred watts, which is almost no strain on the commercial power line. Therefore, it is free from accidents caused by instantaneous overloads (rush currents) that can often occur when constructing large test systems, and it is possible to operate a large system consisting of tens of thousands of test modules with only a small contract power of about 5 watts instead of drawing a power line of tens of KW.

The recycled energy generated by each system can be shared with each other over a 220V line by the bidirectional grid inverter 160. The power sharing functionality means that energy can be transferred from the main battery 130 in one system to the main battery 130 in another system over a 220V line.

For example, suppose there are three systems A, B, and C, each consisting of 500 test modules. In this case, the total number of test modules is 1500. If system A is charging and systems B and C perform discharging test, the excess energy recovered by systems B and C during discharge can be transferred to system A via the 220V line.

In another example, energy can be transferred when the operating plants are geographically separated. When Factory A sends recycled energy to the KEPCO 220V line, its meter accumulates − (negative) power, and when Factory B consumes it in another region, its meter increases, so the following calculation can be established.

Total power consumption=Factory B consumption power−Factory A transferring power

This can be regarded as a virtual transfer of power, as the amount to be paid to KEPCO is greatly reduced, as the power transfer fee is collected from Factory A and paid by Factory B. If this is applied to the secondary battery recycling industry, the energy recovered from large-scale waste batteries could be sold to KEPCO or the power exchange through a grid inverter.

This assumes the situation in South Korea, but the same concept can be applied to various commercial power sources other than 220V depending on the situation in each country.

In addition, the main battery 130 may also provide UPS functionality. In the event of a power outage, the system can be operated with energy from the main battery 130 and share energy with other systems through the bidirectional grid inverter 160, which can serve the same function without the need for a separate UPS.

Referring to FIG. 2, the cell test module 200 includes an isolation power supply (bidirectional transfer DC-converter) 290 to operate the circuitry of each module, individual constant current sources and constant voltage sources 250 to charge the test cells (single cell battery cells), a booster converter and constant current charger 270 to act as a variable load (electronic load) during test cell discharge, and a control board 220 for test operation of the test cells.

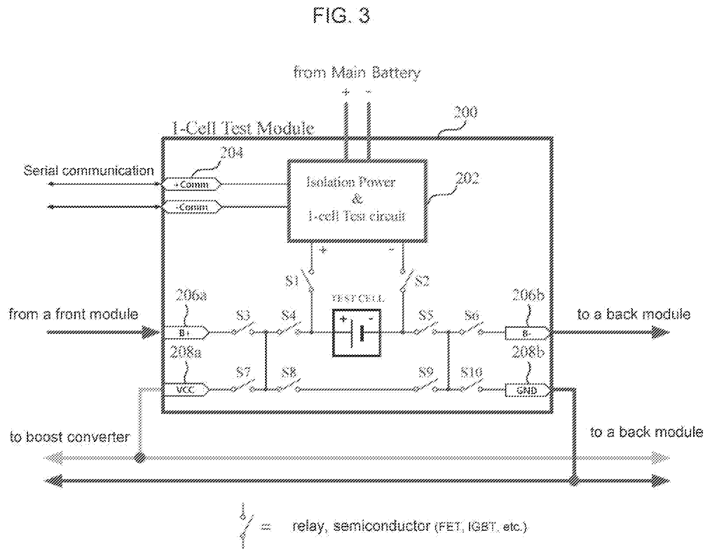

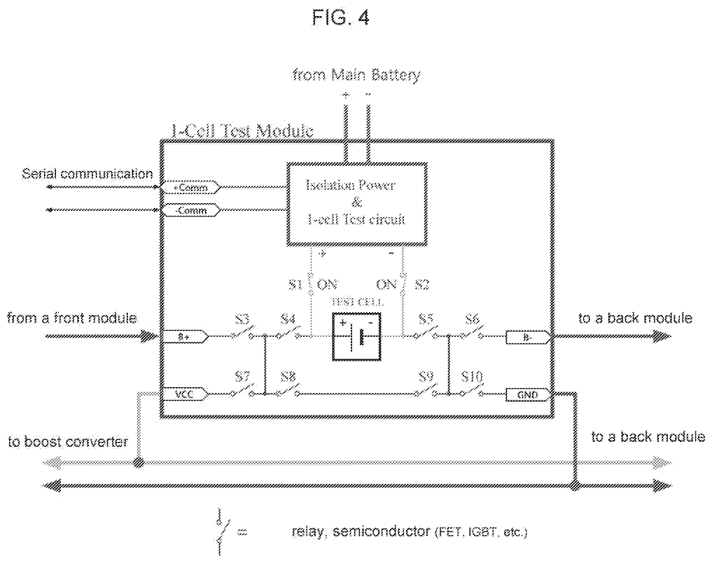

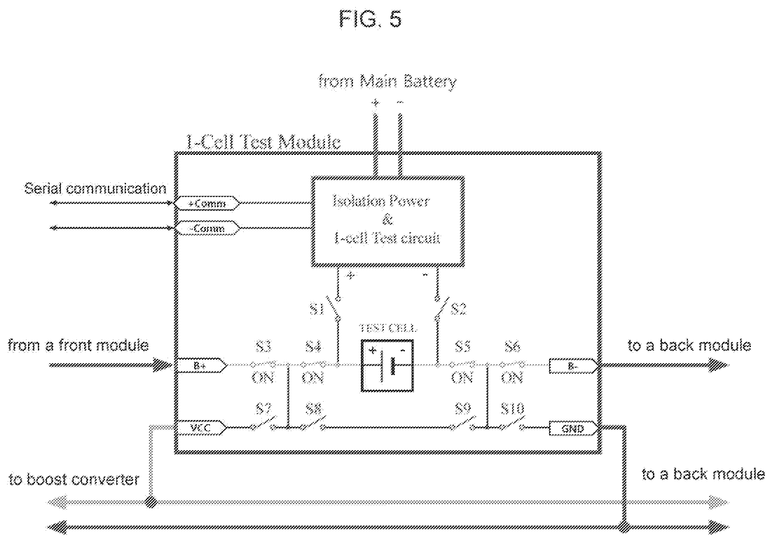

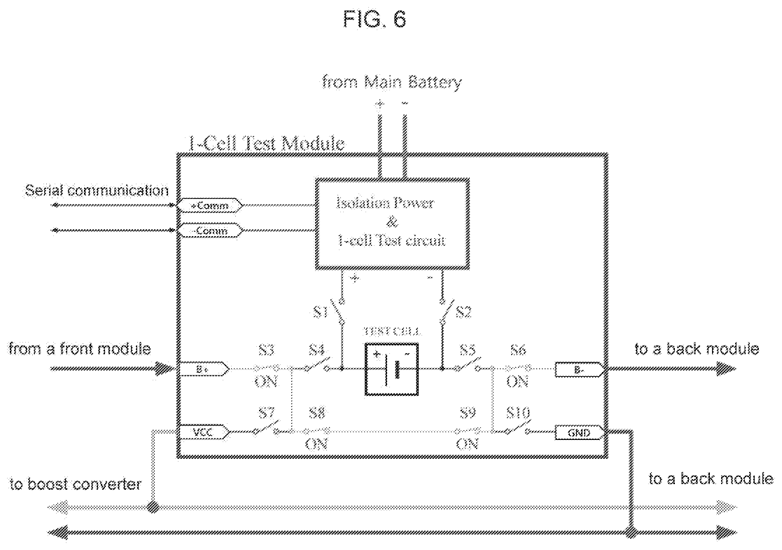

FIG. 3 is a diagram illustrating a circuit configuration of a cell test module according to one embodiment of the present invention, showing a reset state after power input, FIG. 4 is a switch connection diagram when testing a single cell, FIG. 5 is a switch connection diagram when connecting in series, and FIG. 6 is a bad cell avoidance switch connection diagram.

The cell test module 200 includes an isolation power supply and single cell test circuit 202, a communication terminal 204, module connection terminals 206a, 206b (sometimes referred to as “206”), power terminals 208a, 208b (sometimes referred to as “208”), and switches S1 through S10 that control the connection of each terminal. In this embodiment, the switches may be relays or semiconductors such as FETs, IGBTs, etc.

The isolation power supply and single cell test circuit 202 provides an individual power source for various tests (capacity, characterization, etc.) on the test cell 10. The isolation power supply and the single cell test circuit 202 is connected to a power line from the main battery 130 to provide power for testing. In addition, a communication terminal 204 is connected, which may receive control signals from the main control unit 120 to control switch connections for performing the single cell test and/or battery pack verification, and to ensure that the appropriate test and/or verification is performed.

A first switch S1 and a second switch S2 are interposed between the anode and cathode of the test cell 10, respectively, and the isolation power supply and the single cell test circuit 202.

Between the first module connection terminal 206a, which is connected to the front module, and the second module connection terminal 206b, which is connected to the back module, a third switch S3, a fourth switch S4, the test cell 10, a fifth switch S5, and a sixth switch S6 are connected sequentially.

Between the VCC terminal and the GND terminal of the power terminal 208, a seventh switch (S7), an eighth switch (S8), a ninth switch (S9), and a tenth switch (S10) are connected sequentially.

The first node between the third switch (S3) and the fourth switch (S4) and the third node between the seventh switch (S7) and the eighth switch (S8) are connected to each other. The second node between the fifth switch (S5) and the sixth switch (S6), and the fourth node between the ninth switch (S9) and the tenth switch (S10) are connected to each other.

In the reset state after power is applied, all switches are in the OFF state, as shown in FIG. 3.

Then, when performing a single cell test, the first switch S1 and the second switch S2 are switched to the ON state, as shown in FIG. 4, to connect the test cell 10 with the isolation power supply and the single cell test circuit 202. Then, a test is performed on the test cell 10 through a predetermined process.

FIG. 5 illustrates an example of connecting the test cell 10 in series when the test cell 10 is connected to other modules for battery pack verification after the single cell test is completed. In this case, the first switch S1 and the second switch S2 are again turned OFF, and the third switch S3, the fourth switch S4, the fifth switch S5, and the sixth switch S6 are turned ON, so that the test cell 10 can be connected in series between the front module and the back module.

If the test determines a bad cell, a switch connection diagram for avoiding the bad cell is shown in FIG. 6. The third switch S3, eighth switch S8, ninth switch S9, and sixth switch S6 are switched to the ON state to prevent the test cell 10 from being disposed in the line from the front module to the back module, thereby avoiding the bad cell.

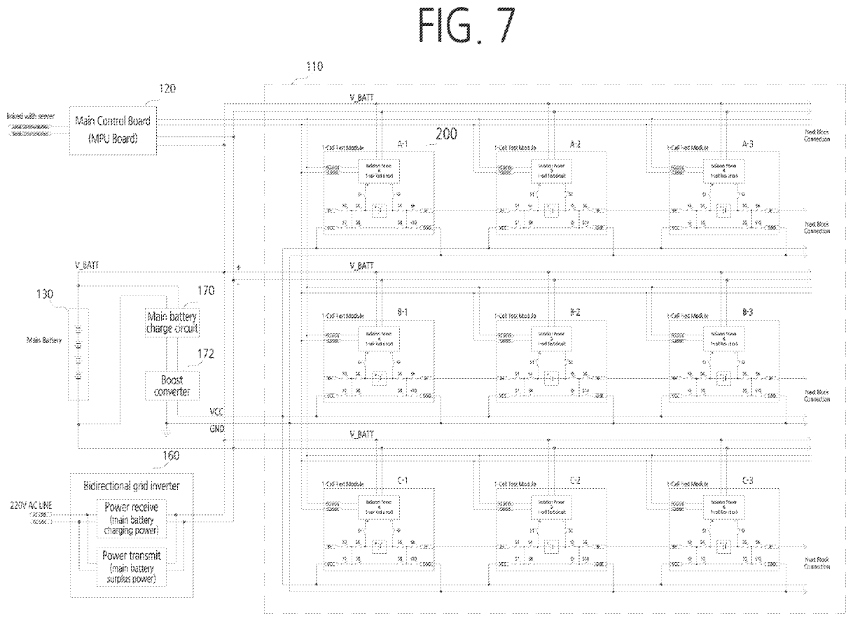

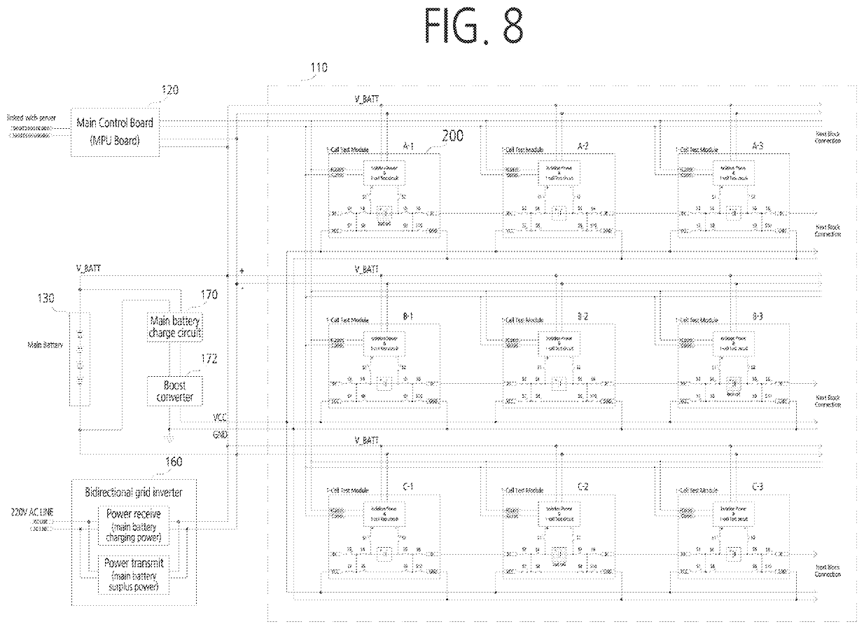

FIG. 7 is a conceptual diagram of the input and output connections and power supply of each test module, and FIG. 8 is a conceptual diagram showing the connection relationship reflecting the avoidance of bad cells.

Referring to FIG. 7, a case is illustrated where the cell test module 200 is connected in a three-row type. This is an example, although they may be connected to have two, four or more rows.

Each of the cell test modules 200 is connected to the main control unit 120 via a communication terminal 204, to which control signals may be transmitted.

In addition, the cell test modules 200 are powered and operated by the main battery 130, i.e., the main battery 130 can be used as a power source as a recycling battery that can simultaneously charge all the single cell cells and recover and store all the power when discharged.

In addition, the main battery charging circuit 170, which charges the main battery 130 with the power recovered during the discharge test, and the boost converter 172, which functions as a variable load (electronic load), may be connected.

In an energy recovery scheme for a single cell discharge test, an electronic load 270 included in the cell test module 200 is responsible for recovering power from the single cell, and a bidirectional transfer DC-converter 290 is responsible for charging the main battery 130 (a low power energy recovery and charging method for single cell testing only).

When discharging a pack combination (a combination of multiple single cell batteries by XY matrix switching), the boost converter 172 is responsible for power recovery and the main battery charging circuit 170 is responsible for charging the main battery 130 (a large power energy recovery and charging method for pack testing only).

In the Pack combination discharge, the boost converter 172 functions as a variable load (electronic load) and the main battery functions as a fixed load (dummy load).

In addition, a bidirectional grid inverter 160 may be connected that exports surplus power from the main battery through the AC line and draws from the AC line to replenish the main battery in the event of a power shortage.

Each of the cell test modules 200 has an independent isolation power supply source and charge/discharge circuit. Thus, after testing the single cell, the main control unit 120 records the XY coordinate data of the good cell and the bad cell in its memory.

Referring to FIG. 8, in a three-row connection structure divided into rows A, B, and C, if A-1, B-3, and C-2 are determined to be bad cells, the main control unit 120 performs XY matrix switching to avoid them by referring to the XY coordinate data recorded in memory after the single cell test. Then, the charging or discharging performance can be verified by simulating a virtual battery pack by connecting only good cells in two series and three parallel to form a virtual battery pack.

Referring to line A, for the bad cell, A-1, switch control is performed to bypass the test cell at the VCC terminal and lead to the second module connection terminal (S7, S8, S9, S6—ON). For the normal cell, A-2, perform switch control from the first module connection terminal to the second module connection terminal bypassing the test cell (S3, S4, S5, S6—ON). If the normal cell, A-3, is the last cell, perform switch control from the first module connection terminal to the test cell to the GND terminal (S3, S4, S5, S10—ON).

Referring to line B, for normal cell B-1, switch control is performed from the VCC terminal through the test cell to the second module connection terminal (S7, S4, S5, S6—ON). For the normal cell, B-2, perform switch control from the first module connection terminal through the test cell to the second module connection terminal (S3, S4, S5, S6—ON). If the bad cell, B-3, is the last cell, perform switch control from the first module connection terminal to bypass the test cell and go to the GND terminal (S3, S8, S9, S10—ON).

Referring to line C, for the normal cell, C-1, perform switch control from the VCC terminal to the second module connection terminal bypassing the test cell (S7, S4, S5, S6—ON). For the bad cell, C-2, perform switch control to bypass the test cell at the first module connection terminal and continue to the second module connection terminal (S3, S8, S9, S6—ON). If C-3, the normal cell, is the last cell, perform switch control from the first module connection terminal to the GND terminal bypassing the test cell (S3, S4, S5, S10—ON).

The above-described modular battery cell test method and battery pack verification method may also be implemented in the form of a recording medium comprising computer-executable instructions, such as an application or program module executed by a computer. The computer-readable medium can be any available medium that can be accessed by a computer, and includes both volatile and non-volatile media, and removable and non-removable media. Further, the computer-readable medium may include a computer storage medium. The computer storage medium includes both volatile and non-volatile, detachable and non-detachable media implemented with any method or technology for storing information such as computer-readable instructions, data structures, program modules, or other data.

The aforementioned modular battery cell test method and battery pack verification method may be executed by an application installed by default on the terminal (which may include a program included in a platform or operating system, etc., on board the terminal), or may be executed by an application (i. e., a program) installed by a user directly on the master terminal through an application delivery server, such as an application store server, a web server associated with the application or its services. In this sense, the above-described modular battery cell test method and battery pack verification method may be implemented as an application (i. e., a program) installed by default on a terminal or directly installed by a user, and recorded on a computer-readable recording medium such as a terminal.

Although the above has been described with reference to embodiments of the present invention, it will be understood by one of ordinary skill in the art that various modifications and changes can be made to the present invention without departing from the ideas and scope of the present invention described in the scope of the following patent claims.

What is claimed is:

1. A modular battery cell test and battery pack verification system for testing a battery cell and verifying a battery pack, comprising:
a cell battery test apparatus comprising a plurality of cell test modules for performing tests on single battery cells, and for performing verification on a virtual battery pack in connection with said cell test modules;
a main control unit for transmitting control signals for test and verification to said cell test modules; and
a main battery for supplying power to said cell battery test apparatus or recovering power discharged from said cell battery test apparatus.

2. The modular battery cell test and battery pack verification system of claim 1, wherein said cell test module comprises:
an isolation power supply and single cell test circuit for providing independent power and performing predetermined cell tests on said single cell; and
an input and output terminals that receive control signals from said main control unit, transmit test results, and are hardware switched according to series and parallel connection information after test completion.

3. The modular battery cell test and battery pack verification system of claim 1, wherein said cell battery test apparatus causes a plurality of said cell test modules to be connected in an XY matrix manner, and wherein module connections are controlled to avoid single cells that are determined to be bad cells as a result of the test, thereby creating a packing combination for a virtual battery pack.

4. The modular battery cell test and battery pack verification system of claim 1, wherein said main battery is connected to a bidirectional grid inverter to enable power sharing with other systems.

5. The modular battery cell test and battery pack verification system of claim 1, further comprising a data server storing test results, and configuring a packing combination for a virtual battery pack; and
a printer for printing at least one of cell information corresponding to said test results, and pack information corresponding to verification results for said virtual battery pack, in a form attachable to said single battery cell.

6. The modular battery cell test and battery pack verification system of claim 1, further comprising a data server for storing test results and configuring packing combinations for a hypothetical battery pack; and
a laser marking apparatus that, upon completion of the test, rotates said single cell to directly imprint at least one of cell information corresponding to said test results, and pack information corresponding to verification results for said virtual battery pack, on a surface of said single cell.

7. A cell test module for performing tests on battery cells, comprising:
an isolation power supply and single battery cell test circuit for providing independent power and performing predetermined cell tests on said battery cells;
a communication terminal for receiving control signals from a main control unit and transmitting test results;
a module connection terminal connecting between a front module and a back module;
a power terminal connecting VCC and GND for verification of a virtual battery pack; and
a plurality of switches controlling connections between said single cell, said isolation power supply and single cell test circuit, said module connection terminals, and said power terminals.

8. The cell test module for performing tests on battery cells of claim 7, wherein said plurality of switches comprises, a first switc (S1) interposed between a positive electrode of said battery cell and said isolation power supply and single cell test circuit;
a second switch (S2) interposed between a negative electrode of said battery cell and said isolation power supply and single cell test circuit;
with a third switch (S3), a fourth switch (S4), a fifth switch (S5), and a sixth switch (S6) sequentially disposed between a first module connection terminal connecting to the front module and a second module connection terminal connecting to the back module; and
a seventh switch (S7), an eighth switch (S8), a ninth switch (S9), and a tenth switch (S10) disposed sequentially between a VCC terminal and a GND terminal among said power terminals.

9. The cell test module for performing tests on battery cells of claim 8, wherein only said first switch and said second switch are in the ON state when testing said battery cell.

10. The cell test module for performing tests on battery cells of claim 8, wherein when said battery cell is a normal cell, said first switch and said second switch are OFF during verification on a virtual battery pack, and the switch connections are controlled to pass through said battery cell by controlling the ON/OFF of said third switch to said tenth switch.

11. The cell test module for performing tests on battery cells of claim 8, wherein if said battery cell is a bad cell, said first switch and said second switch are turned OFF during verification of a virtual battery pack, and said switch connections are controlled to bypass said battery cell by controlling the ON/OFF of said third switch to said tenth switch.
